(19) United States
(12) Patent Application Publication
(10) Pub. No.: US 2002/0158261 A1
(43) Pub. Date: Oct. 31, 2002

(54) Light emitting diode layout structure

(76) Inventors: Ming-Tang Lee, Yungho-city (TW); Cheng-I Lin, Taipei (TW); Cheng-Wei Chan, Chungho City (TW); Ping-Kun Lai, Panchiao City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/841,071

(22) Filed: Apr. 25, 2001

(51) Int. Cl. H01L 33/00

(52) U.S. Cl. 257/88; 257/91; 257/99

(57) ABSTRACT

An LED layout structure has a substrate, at least one light emitting chip mounted on a front surface of the substrate. A first conductive wire is formed on the front surface of the substrate to connect with a first pole of the light emitting chip, and then the first conductive wire extends to a back surface of the substrate to form two terminals on the back surface. At least one second conductive wire having a first terminal formed on the front surface of the substrate to connect with a second pole of the light emitting chip, and then the second conductive extends to the back surface of the substrate and back to the front surface to form a second terminal. By applying the LED layout structure to form an LED array arrangement, the wire jumping problem is effectively avoided.

### BACKGROUND OF THE INVENTION

1. Field of the Invention

The present invention relates to a light emitting diode (LED) layout structure, and more particularly to a light emitting diode layout structure being suitable arranged on a single layered printed circuit board for avoiding wire jumping.

2. Description of Related Art

In order to minimize the volume of the electronic products to increase its portability, many elements are fabricated to form as a chip style. With regards to FIG. 5A, a conventional LED structure is shown, wherein a chip (60) is mounted on a first surface of a substrate (50). A first conductive wire (51) is formed on the first surface to connect a first pole of the chip (60), and a second conductive wire (52) is also formed on the first surface to connect with a second pole of the chip (60) via a golden wire (61).

With reference to FIG. 5B, the first pole and the second pole of the chip (60) are respectively indicated by letters K and A.

With reference to FIG. 5C, a second surface of the substrate (50) is shown, wherein the first and second conductive wires (51 and 52) extend to the second surface of the substrate to form two terminals (51′ and 52′) on the second surface.

With reference to FIG. 6, when employing the layout style shown in FIG. 5B to arrange an LED array, i.e. all the same poles of each chip (60) are electrically connected together, the wire jumping (where the wire jumping occurring is indicated by symbol J is unable to avoid. To overcome the wire jumping problem, the PCB is defined with multiple through plated holes to electrically connect same poles of circuit wires formed on both sides of the PCB. Even the through plated holes are employed to avoid the wire jumping problem, when the quantity of the chips is large, the circuit wires layout is still very complex. Thus multi-layered PCB are introduced to avoid wire jumping. However, the cost of making multi-layered PCB is higher than the single layered PCB.

To overcome the shortcomings, the present invention tends to provide an LED layout structure to mitigate and obviate the aforementioned problems.

### SUMMARY OF THE INVENTION

The main objective of the invention tends to provide an LED layout structure on a single layered PCB to reduce the production cost of the PCB, moreover, to avoid the wire jumping problem when multiple LED chips are arranged as an array form.

Other objects, advantages and novel features of the invention will become more apparent from the following detailed description when taken in conjunction with the accompanying drawings.

### BRIEF DESCRIPTION OF THE DRAWINGS

FIGS. 1A to 1C show a first embodiment of an LED layout structure in accordance with the present invention;

FIGS. 2A to 2B show an array form that is arranged by the multiple first embodiment of the LED layout structure shown in FIG. 1;

FIGS. 3A to 3B show a second embodiment of an LED layout structure in accordance with the present invention;

FIG. 4 shows an array form that is arranged by the multiple second embodiment of the LED layout structure shown in FIG. 3;

FIG. 5 is a conventional LED layout structure; and

FIG. 6 shows an array form that is arranged by the conventional LED layout structure shown in FIG. 5.

### DETAILED DESCRIPTION OF THE PREFERRED EMBODIMENT

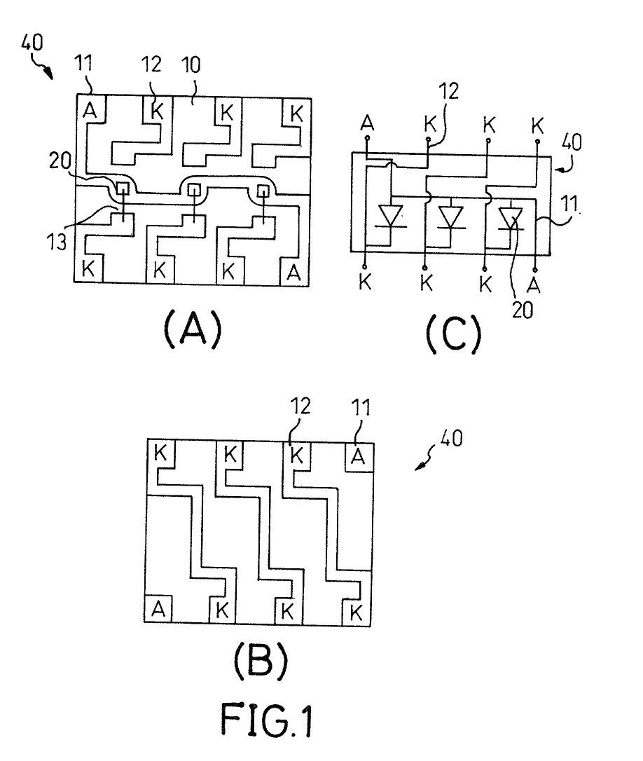

With reference to FIGS. 1A and 1B, a front surface view and a back surface view of a substrate (10) are respectively disclosured. On the front surface, multiple lighting emitting chips (20) are mounted on the substrate (10). A first conductive wire (11) is formed on the front surface of the substrate (10) and to be formed as a slightly diagonal line shape. The first conductive wire (11) is in series connection with a first pole of each light emitting chip (20), and then the first conductive wire extends to the back surface of the substrate (10) to form two terminals on the back surface.

A plurality of second conductive wires (12) are formed on the front surface of the substrate (10), wherein the number of the plurality of second conductive wires is correspond to the number of the light emitting chips (20). On the front surface, each second conductive wire (12) has a first terminal to connected with the second pole of each chip (20) via a golden wire (13), and then each second conductive wire (12) extends to back surface of the substrate (10) and return to the front surface to form a second terminal. When each light emitting chip (20) is connected according forgoing description, an LED (40) is formed.

On the front and back surface of the substrate (10), each second conductive wire (12) does not connect with the first conductive wire (11).

With reference to Fig. IC, a wiring diagram of the LED (40) is shown, wherein each first pole (indicated with letter A) of each light emitting chip (20) is in series connection together by the first conductive wire (11). Each second pole of each light emitting chip (20) is respectively connected with each second conductive wire (12).

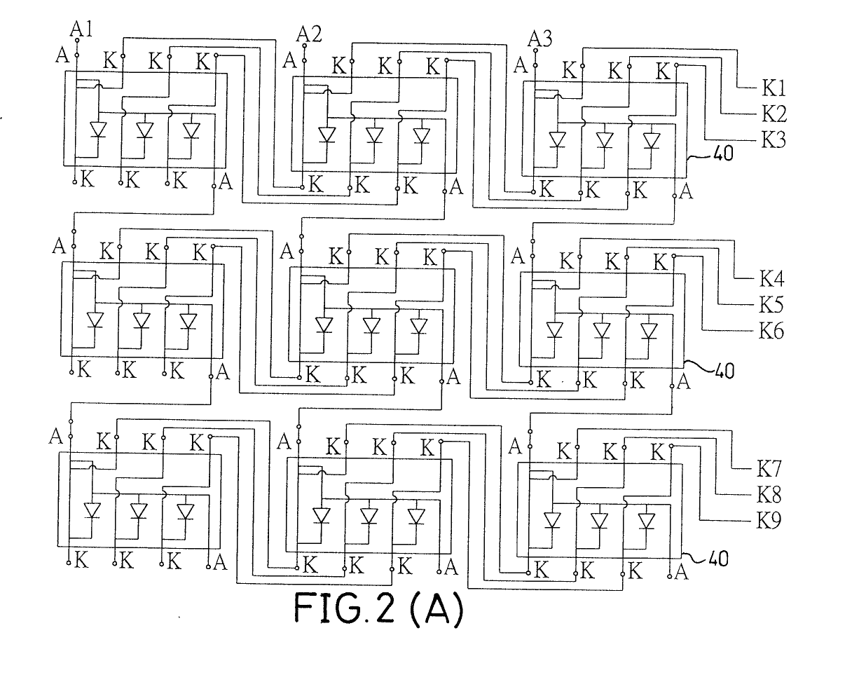

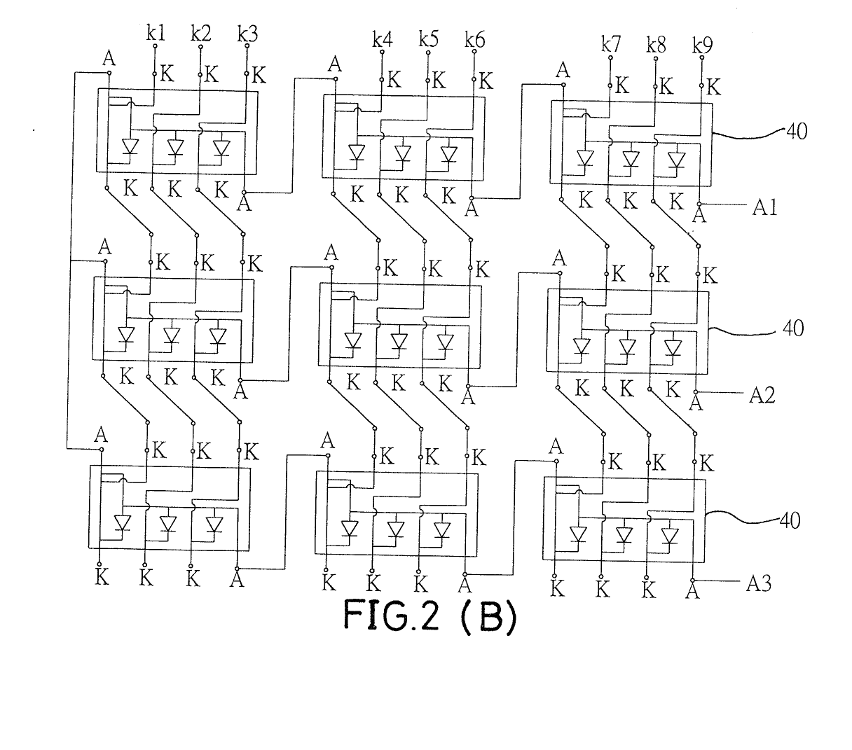

With reference to FIGS. 2A and 2B, when applying the LED layout structure shown in FIG. 1 C to form an array arrangement, there is no wire jumping problem. Each LED (40) has the multiple light emitting chips (20), and each first pole of each light emitting chips (20) is connected together (indicated by A), identically each second pole of each light emitting chips (20) is connected together (indicated by K).

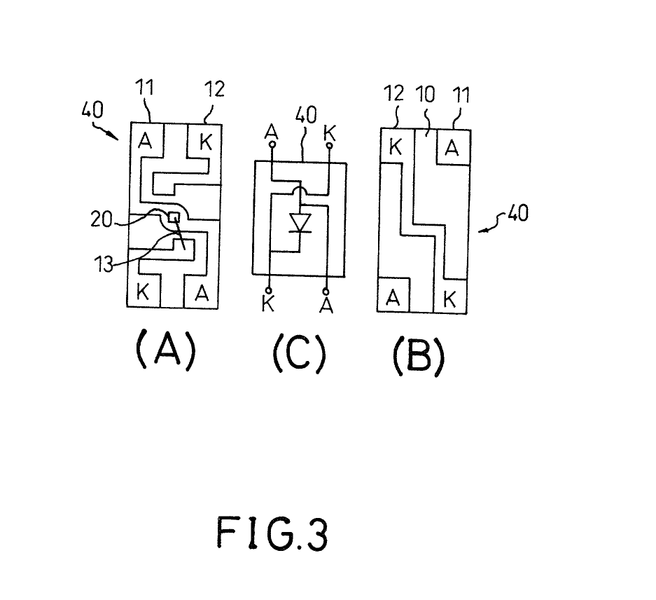

With regards to FIG. 3, a second embodiment of the LED layout structure is shown. In addition to the quantity of the light emitting chips (20) mounted on the substrate (10), the LED (40) layout structure of the second embodiment is basically same as the first embodiment.

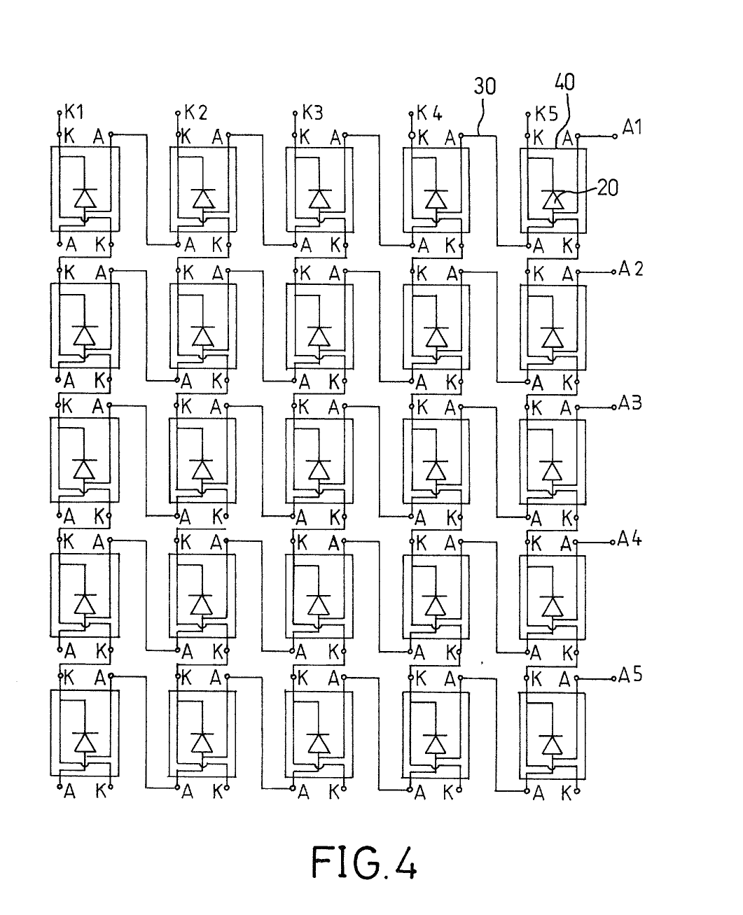

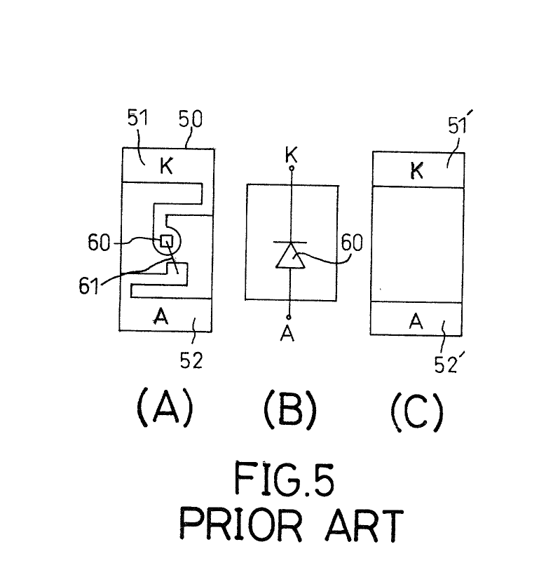

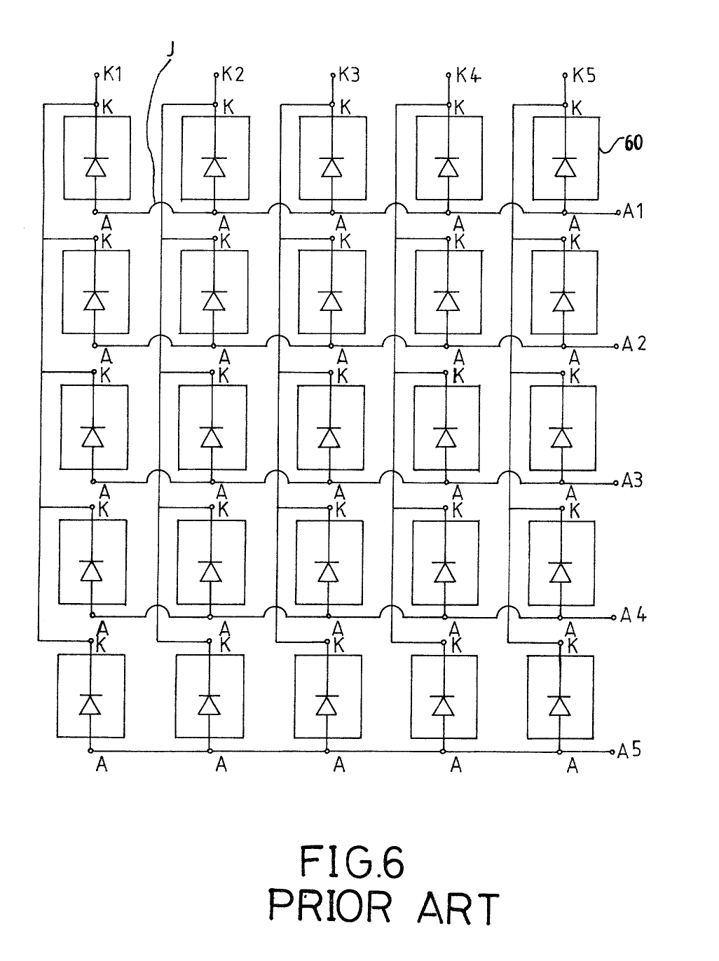

With reference to FIG. 4, when applying the LED (40) layout structure shown in FIG. 3 to form an array arrangement, each first pole of each light emitting chips (20) is connected together (indicated by A), identically each second pole of each light emitting chips (20) are connected together (indicated by K), and there is no wire jumping problem.

According forgoing description, the present invention is suitable to form an LED array layout structure to avoid the wire jumping problem. Furthermore, when taking the present invention to form an Led array layout structure, there is no necessity to fabricated an multi-layered PCB or define multiple through holes on the PCB, so that the cost is greatly reduced.

Although the present invention has been explained in relation to its preferred embodiment, it is to be understood that many other possible modifications and variations can be made without departing from the spirit and scope of the invention as hereinafter claimed.

What is claimed is:

1.An light emitting diode layout structure comprising:
a substrate having a front surface and a back surface;
at least one light emitting chip mounted on the front surface of the substrate, wherein the at least one light emitting chip has a first pole and a second pole;
a first conductive wire formed on the front surface of the substrate and connected with the first pole of the light emitting chip, wherein the first conductive wire extends to the back surface to form two terminals on the back surface; and
at least one second conductive wire formed on the front surface of the substrate, the at least one second conductive wire having a first terminal connected with the second pole of the at least one light emitting chip, and then the at least one second conductive wire extending to the back surface of the substrate and back to the front surface to form a second terminal.

2. The light emitting diode layout structure as claimed in claim 1, wherein the first conductive wire formed on the front surface of the substrate is formed as a slightly diagonal line shape.

3. The light emitting diode layout structure as claimed in claim 2, wherein the at least one second conductive wire is connected with the second pole of the at least one light emitting chip via a golden wire.
